(19) United States
(12) Patent Application Publication
(10) Pub. No.: US 2014/0318603 A1
(43) Pub. Date: Oct. 30, 2014

(54) All Plastic Solar Panel

(71) Applicant: George Philip Tharisayi, Berkeley, CA (US)

(72) Inventor: George Philip Tharisayi, Berkeley, CA (US)

(21) Appl. No.: 14/155,542

(22) Filed: Jan. 15, 2014

Related U.S. Application Data
(60) Provisional application No. 61/854,536, filed on Apr. 26, 2013.

(51) Int. Cl. H01L 31/042; H01L 31/048

(52) U.S. Cl. CPC H01L 31/0424; H01L 31/048
USPC 136/251

(57) ABSTRACT

The present invention generally relates to integration of solar cells into All Plastic Solar Panel which is not only light weight, long lasting and cost effective, but it is also capable of providing excellent functional support to the network of solar cells, assembled within the said solar panel, towards receiving solar radiations effectively and carrying out photovoltaic effects therein.

All Plastic Solar Panel discloses a solar panel which is particularly made of multilayer and transparent plastic sheets, wherein said panel provides excellent solar radiation transmittance and also provides effective barrier against moisture and air, reaching the underlying solar cell components.

### TECHNICAL FIELD OF THE INVENTION

The present invention generally relates to integration of solar cells into All Plastic Solar Panel which is not only light weight, long lasting and cost effective, but it is also capable of providing excellent functional support to the network of solar cells, assembled within the said solar panel, towards receiving solar radiations effectively and carrying out photovoltaic effects therein.

All Plastic Solar Panel discloses a solar panel which is particularly made of multilayer and transparent plastic sheets, wherein said panel provides excellent solar radiation transmittance and also provides effective barrier against moisture and air, reaching the underlying solar cell components.

### BACKGROUND AND OBJECT OF THE INVENTION

Solar cells are often electrically connected and encapsulated as a panel. Solar panels often have a sheet of glass on the front (sun up) side, allowing light to pass while protecting the semiconductor wafers from abrasion and impact due to wind-driven debris, rain, hail, etc.

Solar cells are also usually connected in series in panels, creating an additive voltage. Connecting solar cells in parallel will yield a higher current; however, very significant problems exist with parallel connections. For example, shadow effects can shut down the weaker (less illuminated) parallel string (a number of series connected cells) causing substantial power loss and even damaging the weaker string because of the excessive reverse bias applied to the shadowed cells by their illuminated partners. Strings of series cells are usually handled independently and not connected in parallel, special paralleling circuits are the exceptions.

Various kinds of solar cells, depending upon the efficiency and use are being manufactured keeping in view the cost involved therein. The most prevalent bulk material for solar cells is crystalline silicon (abbreviated as a group as c-Si), also known as “solar grade silicon”. Bulk silicon is separated into multiple categories according to crystallinity and crystal size in the resulting ingot, ribbon, or wafer. Thin-film technologies reduce the amount of material required in creating the active material of solar cell. Most thin film solar cells are sandwiched between two panes of glass to make a module. Since silicon solar panels only use one pane of glass, thin film panels are approximately twice as heavy as crystalline silicon panels.

Solar cells are being manufactured using different technologies, depending upon the efficiency, cost, type of application and available area for mounting the solar panels.

A solar panel is a set of solar photovoltaic modules, electrically connected and mounted on a supporting structure. A photovoltaic module is a packaged, connected assembly of solar cells. The solar module can be used as a component of a larger photovoltaic system to generate and supply electricity in commercial and residential applications. Each module is rated by its DC output power under standard test conditions (STC), and typically ranges from 100 to 320 watts. As a single solar module can produce only a limited amount of power; most installations contain multiple modules. A photovoltaic system typically includes a panel or an array of solar modules, an inverter, and sometimes a battery and/or solar tracker and interconnection wiring.

Assembly and encapsulation of solar cells in the solar panels/modules may affect the efficiency of solar cells, mainly relating to reflectance efficiency, thermodynamic efficiency, charge carrier separation efficiency and conductive efficiency of solar cells. Depending on construction, photovoltaic modules can produce electricity from a range of frequencies of light, but usually cannot cover the entire solar range (specifically, ultraviolet, infrared and low or diffused light).

Current challenges relating to the manufacturing of solar cell and solar panel/module include: (a) manufacturing cost effective solar panel/module to encapsulate various types of solar cells, made in varying dimensions; (b) enhancing the efficiency of solar panel/module towards maximum transmission of solar light to solar cells; (c) improving the structural features, namely making solar panels/modules light weight, more durable, better abrasion and weather-proof features, using polymeric materials with improved efficacy, making the panel/module more flexible/portable, and adoptable to diverse kind of surfaces/areas such as roof or wall etc.

In the recent practice in the concerned field, thin film solar panels are commercially available for installation onto the roofs of buildings, either applied onto the finished roof, or integrated into the roof covering. The advantage over traditional PV panels is that they are very low in weight, are not subject to wind lifting, and can be walked on (with care). The comparable disadvantages are increased cost and reduced efficiency.

Object of present invention is to propose a new kind of solar panel, which is basically an ‘All Plastic Solar Panel’ for encapsulation of solar cells.

The proposed All Plastic Solar Panel particularly comprises of single or multilayer plastic sheet or film towards creation of the solar panel/module for encapsulating various kinds of solar cells, including the conventional crystalline silicon wafer with its contact grid made from bus bars.

The proposed All Plastic Solar Panel/module is very much compatible to the conventional glass using panels/modules and is capable of providing excellent solar radiation transmission and provide effective barrier against moisture and air reaching the underlying solar cells components.

The proposed All Plastic Solar Panel is provided, where conductors overlap, with an additional layer of dielectric ceramic tape for additional and longer lasting dielectric protection. A dielectric failure between conductors will short circuit the conductors and generally lead to partial or complete failure of any solar panel.

Another object of the present invention is to propose a method of making of the proposed All Plastic Solar Panel.

### SUMMARY OF THE INVENTION

The All Plastic Solar Panel is basically for the encapsulation of solar cells towards receiving maximum solar radiations for performing the photovoltaic actions effectively. It does not apply the conventional glass components for encapsulating solar cells. Due to application of plastic components in the panel, it is very light weight, durable and has all resistance against diverse weather conditions. Further it is capable of being mounted on all kind of available spaces/areas like roof, wall or towers in very flexible manner.

Even though the whole solar cell encapsulating module is made of single or preferably multiple plastic sheets/films, its top surface is made to receive optimum sun light and transmit it effectively to the solar cell components therein below for performing the photovoltaic action, utilizing maximum possible ranges of frequencies of radiations received.

The proposed All Plastic Solar Panels herein are made by such a method, particularly towards compositing multiple plastic sheets/films, that its functioning towards solar radiation absorption and transmission to the solar cell components encapsulated therein below, becomes very much comparable to the conventional glass containing solar panels.

The accompanying drawings herein below describe the working of All Plastic Solar Panel. In one preferred embodiment, solar cells, in a desired pattern, are sandwiched between the layers of plastic in such a manner that the amount of light falling on solar cells encapsulated therein, would not get adversely affected/restricted/reflected and the said plastic encapsulating top layer supports the maximum absorption of light. The proposed plastic encapsulating top layer, due to presence of more than one layers of plastic sheets having specific light refracting/absorbing behavior, preferably show as effective light/radiation transmission to the solar cells as in case of conventional glass plates being used in the conventional solar panels.

Thus the basic novelty and inventiveness involved in the present invention is to make solar panels cost effective, strong and long-lasting, but without compromising with the quality of performance with respect to the conventional practice of the field.

Refractive index of the top plastic cover to the solar panel is so adjusted, mainly by the suitable combination of more than one polymeric sheet, optionally varying the density or quality of polymer, that the said top plastic cover receives and transfers wide range of solar light for longer duration of the day time.

### BRIEF DESCRIPTION OF THE DRAWINGS

The exemplary embodiments of the proposed All Plastic solar panel is substantially being described herein below supported with illustrative drawings.

FIG. 1: The schematic top view of one basic embodiment of the solar panel encapsulating the assembly of solar cells.

FIG. 2: Schematic plan (schematic sectional view A-A) of the proposed all plastic solar panel for accommodating solar cells.

FIG. 3: It schematically shows the conventional use of dielectric tape and dielectric ceramic tape to protect the electric conductor (bus or tap wire) and bottom conductor from dielectric failure with time.

### DETAILED DESCRIPTION OF DRAWINGS

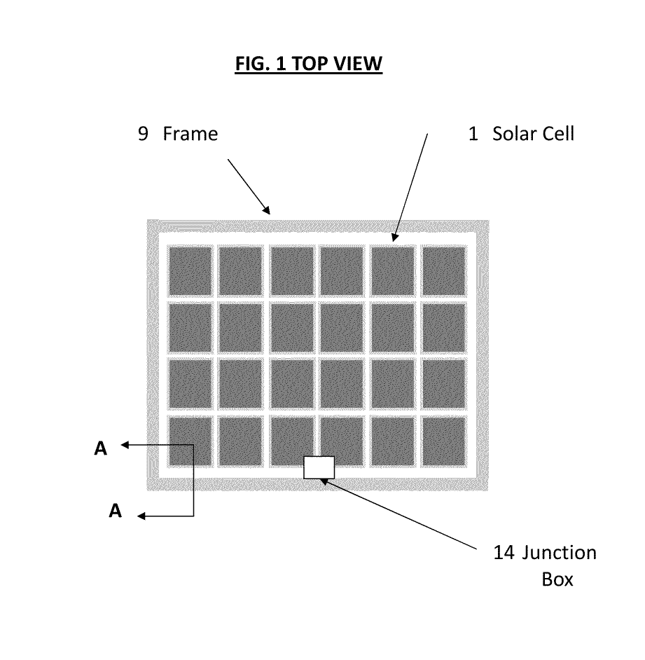

FIG. 1 is the top view of the All Plastic Solar Panel, wherein it accommodates a group of multiple solar cells (1) arranged in a particular fashion on a panel/module, including the arrangement of electric conductors (bus or tab wire) therein. The said drawing shows the frame 9 of the panel, made of plastic of fiber reinforced plastic for enclosing and supporting solar cells and all parts and layers described herein. Electric power generated from solar cells (1) is combined through tabbing and bus wires by series and parallel connections to reach the specified voltage and current and is connected to the terminals in junction box (14). Diode or diodes may be used in the junction box (14), as generally used in the present art.

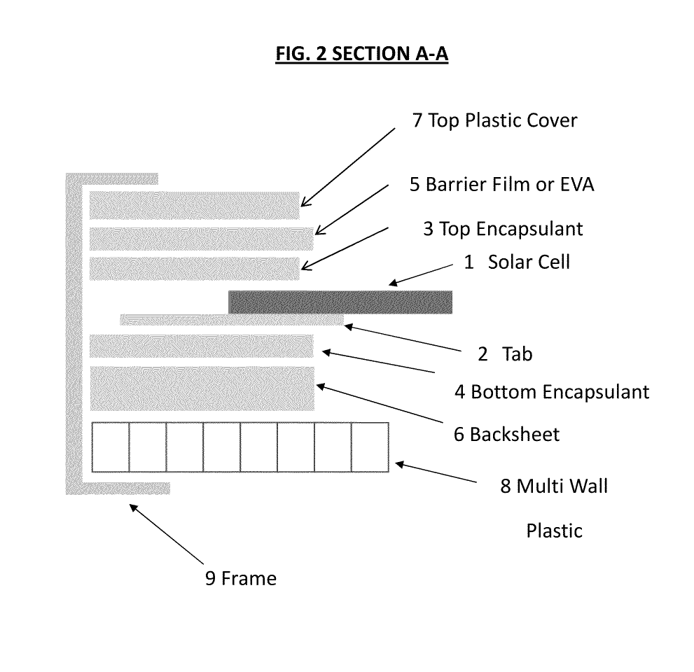

FIG. 2 mainly illustrates the schematic plan for the construction of the proposed all plastic solar panel herein. The solar cell or the group of multiple solar cells, being represented by numeral (1) herein, including tabbing wires (2), is encapsulated between a top encapsulant plastic film (3) and a bottom encapsulant plastic film (4). The top transparent film (5), comprising of single or multiple layers, is provisioned in one optional embodiment of the proposed solar panel, preferably to provide a transparent top cover and to provide a barrier against moisture and air. The bottom plastic film (6), generally known as back sheet which is either transparent or opaque and it is provisioned in one optional embodiment of the proposed solar panel preferably to provide a barrier against moisture and air. A top weather protection film (7), made from single or multilayer plastic sheet(s) or polycarbonate, is optionally provisioned in a preferred embodiment of the proposed solar panel. A bottom support sheet (8) is provided below the solar cell assembly, wherein it is made from multi wall plastic or molded plastic structure, mainly towards additional rigidity to the panel/module. All such structural encapsulating components of the proposed all plastic solar panel are enclosed in a frame (9), made from plastic or fiber reinforced plastic, which supports the overall assembly of the solar cell therein and the parts and layers therein.

Apart from providing the effective encapsulation to the assembly of solar cells in the panel, the combination of multiple layers of plastic films or sheets or structural molds, mainly at the top of the solar cell(s), involve the selection of suitable combined light-refracting property (or the refractive index) of the combined encapsulating layer therein. The selection of said combined refractive index, preferably at the top combined cover layer is so selected to support the maximum absorption of effective solar radiation during the day time for effectively carrying out photovoltaic reactions for longer duration.

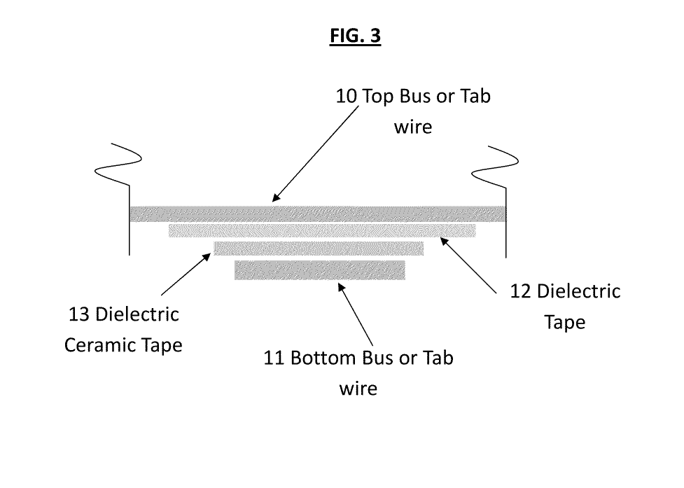

FIG. 3 mainly explains the use of dielectric tape (12) and dielectric ceramic tape (13) in the proposed all plastic solar panel, wherein they are responsible to protect an electric conductor (bus or tab wire) (10) and the bottom conductor (11) from dielectric failure with time during the life of the solar panel. A dielectric failure between conductors will short circuit the conductors and generally lead to partial or complete failure of any solar panel.

An optional embodiment of the proposed All Plastic Solar Panel, encountering case of conductors overlap, is provided with additional layers of ceramic tape in addition to already provisioned dielectric tapes towards longer lasting dielectric protection.

Although the invention has been described with reference to specific embodiments, this description is not meant to be construed in a limiting sense. Various modifications of the disclosed embodiments, as well as alternate embodiments of the invention, will become apparent to persons skilled in the art upon reference to the description of the invention. It is therefore contemplated that such modifications can be made without departing from the spirit or scope of the present invention as defined.

What is claimed is:

1. An All Plastic Solar Panel to integrate solar cells, wherein said All Plastic Solar Panel comprises of a top encapsulating plastic cover layer, a bottom encapsulating plastic cover layer and a plastic frame enclosing the complete assembly of solar cells, its supporting parts therein and said top and bottom encapsulating plastic cover layers; wherein further said top and bottom encapsulating plastic cover layers are preferably made by at least one plastic film and/or sheet and/or structural panel; and wherein the said All Plastic Solar Panel comprises of dielectric tape(s) towards protecting the solar cell assembly from dielectric failure.

2. An All Plastic Solar Panel, as claimed in claim 1, wherein the top encapsulating plastic cover layer comprises of a top encapsulant plastic film, just above the solar cell(s) assembled in said solar panel/module; wherein in one preferred embodiment of said All Plastic Solar Panel the top encapsulating plastic cover layer comprises of combination of top encapsulating plastic film and a top transparent plastic film; and wherein further in another preferred embodiment of said All Plastic Solar Panel the top encapsulating plastic cover layer comprises of combination of top encapsulating plastic film, a top transparent plastic film and a top weather protection film.

3. An All Plastic Solar Panel, as claimed in claim 1, wherein the bottom encapsulating plastic cover layer comprises of a bottom encapsulant plastic film, just below the solar cell(s) assembled in said solar panel/module; wherein in one preferred embodiment of said All Plastic Solar Panel the bottom encapsulating plastic cover layer comprises of combination of bottom encapsulating plastic film and a bottom plastic film as the back sheet; and wherein further in another preferred embodiment of said All Plastic Solar Panel the bottom encapsulating plastic cover layer comprises of combination of bottom encapsulating plastic film, a bottom plastic film as the back sheet, and the rigid bottom support sheet.

4. An All Plastic Solar Panel, as claimed in claim 1, wherein the solar cell(s) assembled in the said solar panel/module, along with the bus and tab wire arrangement therein, is covered within the top encapsulant plastic film and a bottom encapsulant plastic film.

5. An All Plastic Solar Panel, as claimed in claim 1, wherein the top transparent plastic film comprises of single or multiple plastic layers/sheets, wherein said top transparent plastic film is characterized in providing a transparent top cover above the solar cell assembly in the solar panel/module and in providing a barrier against moisture and air.

6. An All Plastic Solar Panel, as claimed in claim 1, wherein the top weather protection film is made of plastic material and preferably of polycarbonate, selected from a group of thermoplastic polymers; wherein said top weather protection film is optionally provisioned in the said All Plastic Solar Panel.

7. An All Plastic Solar Panel, as claimed in claim 1, wherein bottom plastic film as the back sheet is either transparent or opaque and is characterized in providing a barrier against moisture and air.

8. An All Plastic Solar Panel, as claimed in claim 1, wherein the bottom support sheet is made from multi wall plastic or is made from plastic molding, wherein it is provisioned in a preferred embodiment of the said solar panel for rigidity and support to the said solar panel.

9. An All Plastic Solar Panel to integrate solar cells, wherein the plastic frame of the solar panel is provisioned to enclose the complete assembly of solar cells, its supporting parts therein and said top and bottom encapsulating plastic cover layers therein; wherein said plastic frame is made of plastic or fiber reinforced plastic and is made suitably rigid.

10. An All Plastic Solar Panel to integrate solar cells, as claimed in claim 1, wherein the said solar panel comprises of only dielectric tape to protect the electric conductors (bus and/or tab wire) and bottom conductors of the solar cell assembly from dielectric failure with time during the life of the solar panel.

11. An All Plastic Solar Panel to integrate solar cells, as claimed in claim 10, wherein in an optional embodiment of the proposed All Plastic Solar Panel, encountering case of conductors overlap, is provided with additional layers of ceramic tape in addition to already provisioned dielectric tapes towards longer lasting dielectric protection.
